(19) United States
(12) Patent Application Publication
(10) Pub. No.: US 2016/0095218 A1
(43) Pub. Date: Mar. 31, 2016

(54) COMPOSITE WIRING BOARD AND MOUNTING STRUCTURE OF THE SAME

(71) Applicant: KYOCERA Circuit Solutions, Inc., Kyoto (JP)

(72) Inventor: Keizou SAKURAI, Yasu-shi (JP)

(73) Assignee: KYOCERA Circuit Solutions, Inc., Kyoto (JP)

(21) Appl. No.: 14/858,242

(22) Filed: Sep. 18, 2015

(30) Foreign Application Priority Data
Sep. 25, 2014 (JP) 2014-194613

(51) Int. Cl. H05K 1/11; H05K 1/09; H05K 1/03; H05K 1/18; H05K 1/02

(52) U.S. Cl. CPC H05K 1/111; H05K 1/181; H05K 1/115; H05K 1/0218; H05K 1/0306; H05K 1/0313; H05K 1/038; H05K 1/09

(57) ABSTRACT

A composite wiring board includes a first wiring board having an opening for housing an electronic component, and including a plurality of first connection pads on an upper surface and a plurality of second connection pads on a lower surface, and a second wiring board having the electronic component mounted on a lower surface, including a third connection pad provided on the lower surface on an outer peripheral side and bonded to the first connection pad through a solder, and disposed on the first wiring board so as to cover the opening, in which a grounding inner wall conductor layer is deposited on an inner wall of the opening around the electronic component, and a grounding conductor layer is deposited on the lower surface of the second wiring board and connected to the inner wall conductor layer through a solder.

### BACKGROUND OF THE INVENTION

1. Technical Field

The present invention relates to a composite wiring board composed by bonding a flat-plate wiring board on a frame-shaped wiring board through a solder, and a mounting structure of the same.

2. Background

Conventionally, as shown in a schematic cross-sectional view in FIG. 19, there is a known composite wiring board 70 in which a flat-plate second wiring board 60 is mounted on a frame-shaped first wiring board 50 through a solder (JP 2013-51384A). The first wiring board 50 has an opening 50a in its center to house a first electronic component E1 such as a semiconductor element. The first electronic component E1 housed in the opening 50a is mounted on a lower surface of the second wiring board 60. A second electronic component E2 such as a semiconductor element is mounted on an upper surface of the second wiring board 60.

The first wiring board 50 includes an insulating plate 51, a wiring conductor 52, and a solder resist layer 53. A plurality of through-holes 54 are formed in the insulating plate 51 from an upper surface to a lower surface.

The wiring conductor 52 is deposited on each of the upper and the lower surfaces of the insulating plate 51 and a surface in the through-hole 54. The wiring conductor 52 deposited on the upper surface of the insulating plate 51 partially serves as a first connection pad 52a to be bonded to the second wiring board 60. The wiring conductor 52 deposited on the lower surface of the insulating plate 51 partially serves as a second connection pad 52b to be bonded to a third wiring board 80 such as a mother board. The first connection pad 52a and the second connection pad 52b are connected to each other through the wiring conductor 52 in the through-hole 54.

Furthermore, the solder resist layer 53 is deposited on the upper and the lower surfaces of the insulating plate 51. The upper solder resist layer 53 has an opening to expose the first connection pad 52a. The lower solder resist layer 53 has an opening to expose the second connection pad 52b.

The second wiring board 60 includes an insulating plate 61, an insulating layer 62, a wiring conductor 63, and a solder resist layer 64. A plurality of through-holes 65 are formed in the insulating plate 61 from an upper surface to a lower surface. The wiring conductor 63 is deposited on each of the upper and the lower surfaces of the insulating plate 61 and a surface in the through-hole 65.

Furthermore, the insulating layer 62 is stacked on the upper and the lower surfaces of the insulating plate 61. A plurality of via-holes 66 are formed in the insulating layer 62. A bottom surface of each via-hole 66 is the wiring conductor 63 deposited on the upper or lower surface of the insulating plate 61.

The wiring conductor 63 is deposited on a surface of the insulating layer 62 and a surface in the via-hole 66. The wiring conductor 63 deposited on the surface of the lower insulating layer 62 partially serves as a third connection pad 63a at a position opposed to the first connection pad 52a. The third connection pad 63a is connected to the first connection pad 52a through a first solder bump 71. Thus, the first wiring board 50 and the second wiring board 60 are connected to each other.

The other wiring conductor 63 deposited on the surface of the lower insulating layer 62 partially serves as a fourth connection pad 63b in the opening 50a. The fourth connection pad 63b is connected to an electrode of the first electronic component E1 through a second solder bump 72.

The wiring conductor 63 deposited on the surface of the upper insulating layer 62 partially serves as a fifth connection pad 63c. The fifth connection pad 63c is connected to an electrode of the second electronic component E2 through a third solder bump 73.

The solder resist layer 64 is deposited on the surfaces of the upper and the lower insulating layers 62. The lower solder resist layer 64 has an opening to expose the third connection pad 63a and an opening to expose the fourth connection pad 63b. The upper solder resist layer 64 has an opening to expose the fifth connection pad 63c.

The composite wiring board 70 is mounted on the third wiring board 80 in such a manner that after the first electronic component E1 and the second electronic component E2 have been mounted on the second wiring board 60, the second connection pad 52b of the first wiring board 50 is connected to the wiring conductor 81 of the third wiring board 80 such as the mother board through a fourth solder bump 74.

However, according to the conventional composite wiring board 70, an electromagnetic shielding effect is not sufficiently provided for the first electronic component E1 housed in the opening 50a. Consequently, the first electronic component E1 housed in the opening 50a could be externally influenced by an electromagnetic wave. Furthermore, the problem is that it is less likely to externally release heat generated while the first electronic component E1 and the second electronic component E2 are operated.

### SUMMARY

An object of the present invention is to provide a composite wiring board and a mounting structure of the same which are high in electromagnetic shielding effect for an electronic component housed internally, and high in ability to externally release heat generated while the mounted electronic component is operated.

A composite wiring board according to an embodiment of the present invention includes a frame-shaped first wiring board having an opening for housing an electronic component in a center portion, and including a plurality of first connection pads on an upper surface and a plurality of second connection pads on a lower surface, and a flat-plate second wiring board having the electronic component mounted in a center portion on a lower surface, including a third connection pad provided in an outer peripheral portion on the lower surface and bonded to the first connection pad through a solder, and disposed on the first wiring board so as to cover the opening, in which a grounding inner wall conductor layer is deposited on an inner wall of the opening from an upper end to a lower end around the electronic component, and a grounding conductor layer is deposited on the lower surface of the second wiring board and connected to the inner wall conductor layer through a solder.

Amounting structure according to an embodiment of the present invention is composed such that the composite wiring board having the electronic component according to the embodiment of the present invention is mounted on a third wiring board including a connection pad formed on an upper surface and bonded to the second connection pad through a solder, and a grounding conductor layer bonded to the inner wall conductor layer through a solder.

According to the embodiment of the present invention, the composite wiring board includes the grounding inner wall conductor layer deposited on the inner wall of the opening of the first wiring board from the upper surface to the lower surface so as to surround the electronic component in the opening. Therefore, due to the inner wall conductor layer, an electromagnetic shielding effect can be sufficiently provided for the electronic component housed in the opening.

According to the embodiment of the present invention, the composite wiring board includes the grounding conductor layer deposited on the lower surface of the second wiring board having the electronic component, and connected to the inner wall conductor layer of the first wiring board through the solder. Therefore, the heat can be efficiently transmitted from the grounding conductor layer to the inner wall conductor layer of the first wiring board through the solder and externally released. As a result, the composite wiring board has high ability to externally release the heat generated while the electronic component mounted on the second wiring board is operated.

According to the embodiment of the present invention, the mounting structure is composed such that the composite wiring board in the embodiment of the present invention is mounted on the third wiring board having the connection pad formed on the its upper surface and connected to the second connection pad through the solder, and the grounding conductor layer formed on the its upper surface and bonded to the inner wall conductor layer through the solder. As a result, the mounting structure can be high in electromagnetic shielding effect for the electronic component housed internally, and high in ability to externally release the heat generated while the mounted electronic component is operated.

### BRIEF DESCRIPTION OF THE DRAWINGS

FIG. 1 is a schematic cross-sectional view showing a composite wiring board according to one embodiment of the present invention;

FIGS. 2A and 2B to 18A and 18B are schematic top views and schematic cross-sectional views taken along lines X-X in the top views, for describing a method for manufacturing the composite wiring board according to the present invention, respectively; and

FIG. 19 is a schematic cross-sectional view showing a conventional composite wiring board.

### DETAILED DESCRIPTION

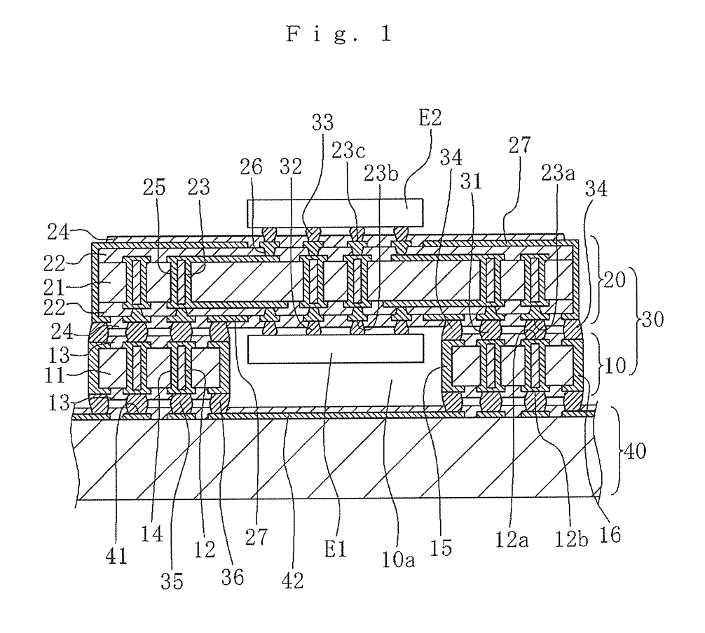

A composite wiring board according to one embodiment of the present invention will be described with reference to the drawings. FIG. 1 is a schematic cross-sectional view showing a composite wiring board 30 in the one embodiment, and the composite wiring board 30 is composed of a first wiring board 10 and a second wiring board 20.

As shown in FIG. 1, the composite wiring board 30 is configured such that the flat-plate second wiring board 20 is bonded to the frame-shaped first wiring board 10. An opening 10a is formed in a center portion of the first wiring board 10 to house an electronic component E1 such as a semiconductor element. The first electronic component E1 housed in the opening 10a is mounted on a lower surface of the second wiring board 20. A second electronic component E2 such as a semiconductor element is mounted on an upper surface of the second wiring board 20.

### First Wiring Board

The first wiring board 10 includes an insulating plate 11, a wiring conductor 12, and a solder resist layer 13. The insulating plate 11 is composed of a thermosetting resin plate containing glass cloth. A plurality of through-holes 14 are formed in the insulating plate 11 from an upper surface to a lower surface.

The wiring conductor 12 is deposited on the upper and the lower surfaces of the insulating plate 11 and a surface in the through-hole 14. The wiring conductor 12 is formed of a material such as copper. The wiring conductor 12 deposited on the upper surface of the insulating plate 11 partially serves as a first connection pad 12a to be bonded to the second wiring board 20. The wiring conductor 12 deposited on the lower surface of the insulating plate 11 partially serves as a second connection pad 12b to be bonded to a third wiring board 40 such as a mother board. The first connection pad 12a and the second connection pad 12b are connected to each other through the wiring conductor 12 in the through-hole 14.

An inner wall conductor layer 15 is deposited on an inner wall of the opening 10a of the insulating plate 11 from its upper end to its lower end. The inner wall conductor layer 15 is deposited on an approximately whole periphery of the inner wall of the opening 10a so as to surround the first electronic component E1 except for a part of the inner wall of the opening 10a. The inner wall conductor layer 15 includes a copper plated layer, for example. The inner wall conductor layer 15 has a thickness of about 5 μm to 40 μm. Since the inner wall conductor layer 15 is deposited on the inner wall of the opening 10a so as to surround the first electronic component E1, an electromagnetic shielding effect can be enhanced for the first electronic component E1 housed in the opening 10a.

An outer wall conductor layer 16 is deposited on an outer peripheral wall of the insulating plate 11 from its upper end to its lower end. The outer wall conductor layer 16 is deposited on an approximately whole periphery of the outer wall of the insulating plate 11 except for a part of the outer peripheral wall of the insulating plate 11. The outer wall conductor layer 16 includes a copper plated layer. The outer wall conductor layer 16 has a thickness of about 5 μm to 40 μm. Since the outer wall conductor layer 16 is deposited on the approximately whole surface of the outer peripheral wall of the insulating plate 11 except for a part of the outer peripheral wall of the insulating plate 11, the electromagnetic shielding effect can be enhanced for the first electronic component E1 housed in the opening 10a.

A solder resist layer 13 is deposited on each of the upper and lower surfaces of the insulating plate 11. The solder resist layer 13 is formed of a thermosetting resin such as acrylic modified epoxy resin. The upper solder resist layer 13 has an opening to expose the first connection pad 12a. In addition, an upper end of the inner wall conductor layer 15 and an upper end of the outer wall conductor layer 16 are exposed. The lower solder resist layer 13 has an opening to expose the second connection pad 12b. In addition, a lower end of the inner wall conductor layer 15 and a lower end of the outer wall conductor layer 16 are exposed.

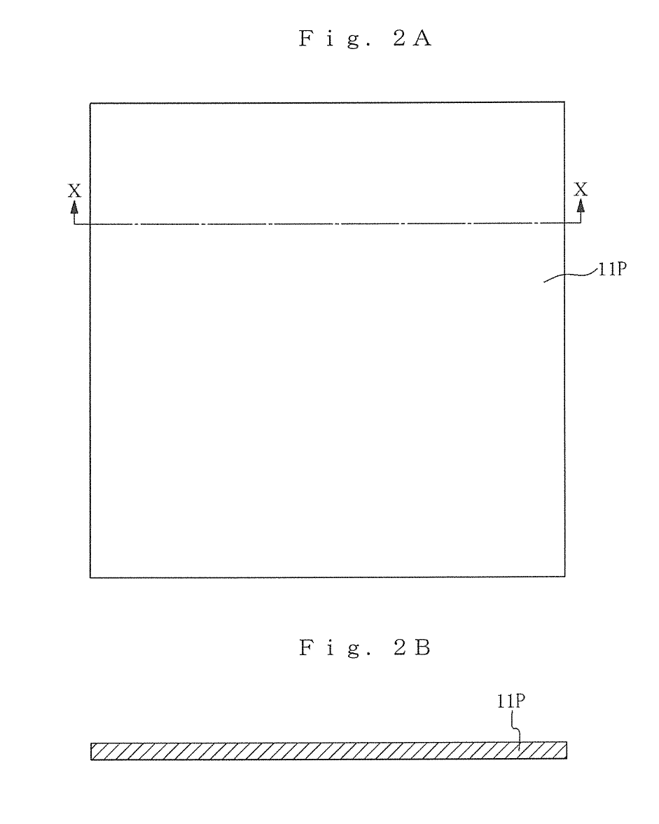

A method for manufacturing the first wiring board 10 will be described with reference to FIGS. 2A and 2B to 11A and 11B. FIGS. 2A and 2B to 11A and 11B show a case where four first wiring boards 10 are manufactured from one panel. FIGS. 2A to 11A show schematic top views of the panel, and FIGS. 2B to 11B show schematic cross-sectional views taken along lines X-X in FIGS. 2A to 11A, respectively.

First, as shown in FIGS. 2A and 2B, a resin panel 11P for the insulating plate 11 is prepared. The resin panel 11P is a thermosetting resin plate containing glass cloth, for example.

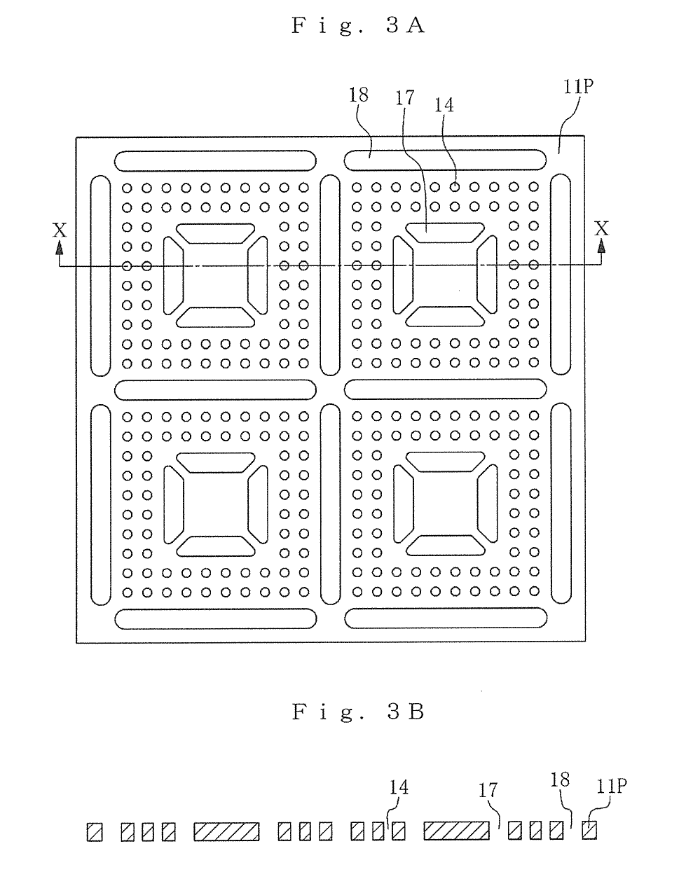

Subsequently, as shown in FIGS. 3A and 3B, the through-holes 14 are formed in the resin panel 11P, first slits 17 are formed so as to be in contact with the inner periphery of the opening 10a of the insulating plate 11, and second slits 18 are formed so as to be in contact with the outer periphery of the insulating plate 11. The through-holes 14 are formed by the drill processing. The first slits 17 and second slits 18 are formed by router processing.

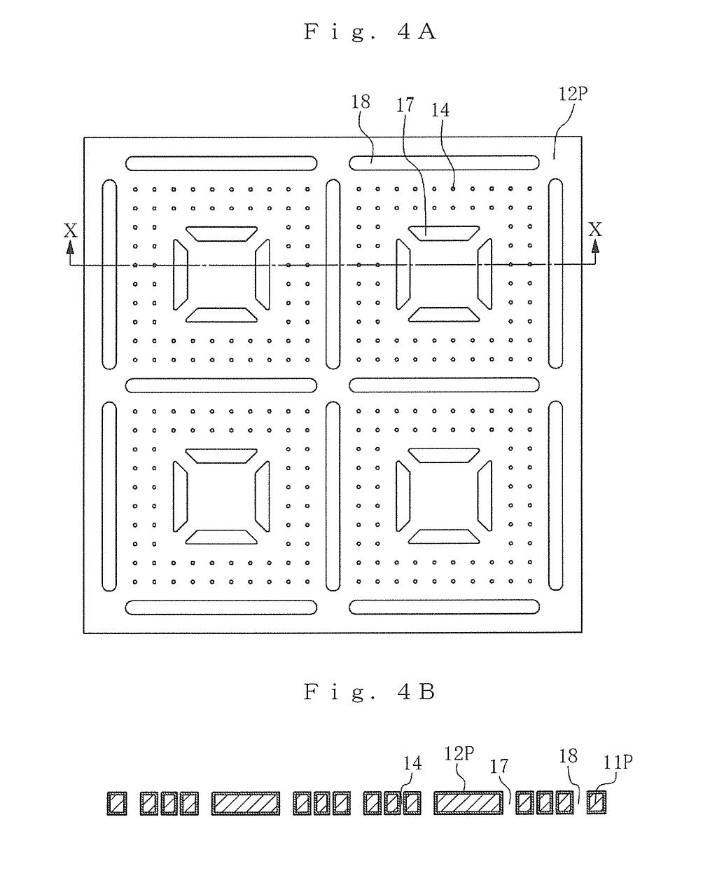

Subsequently, as shown in FIGS. 4A and 4B, a copper plated layer 12P is deposited on each of an upper and a lower surfaces of the resin panel 11P, a surface in the through-hole 14, and whole surfaces in the first slit 17 and the second slit 18. The copper plated layer 12P is formed by sequentially depositing a non-electrolytic copper plated layer having a thickness of about 0.1 μm to 1 μm and an electrolytic copper plated layer having a thickness of about 5 μm to 20 μm.

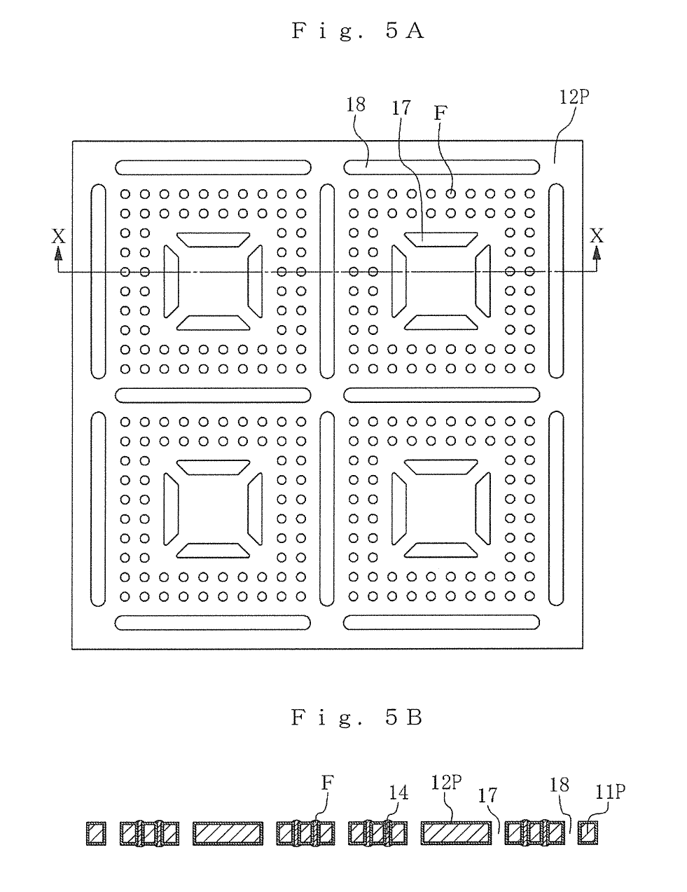

Subsequently, as shown in FIGS. 5A and 5B, the through-hole 14 is filled with a hole-filling resin F. The hole-filling resin F in the form of uncured thermosetting resin paste is filled in the through-hole 14 by a printing method and then thermally cured.

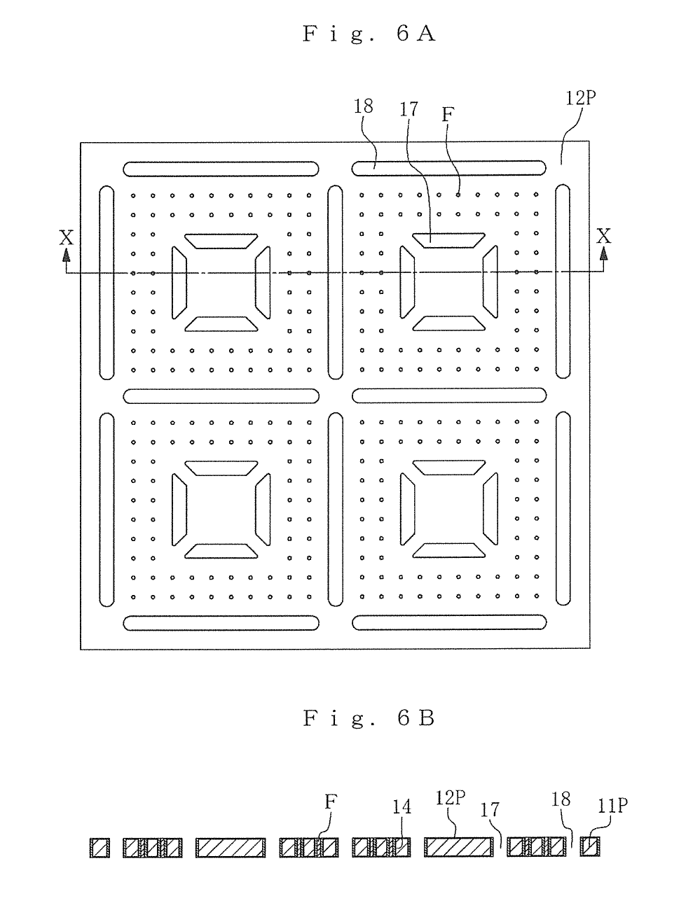

Subsequently, as shown in FIGS. 6A and 6B, the hole-filling resin F partially projecting from the copper plated layer 12P is ground and removed to be planarized together with the copper plated layer 12P on each of the upper and lower surfaces. Consequently, the copper plated layer 12P has a thickness of about 1 μm to 5 μm on each of the upper and lower surfaces of the resin panel 11P. The grinding operation is performed with a roll-grinding machine or a belt-grinding machine. In addition, chemical grinding may be combined.

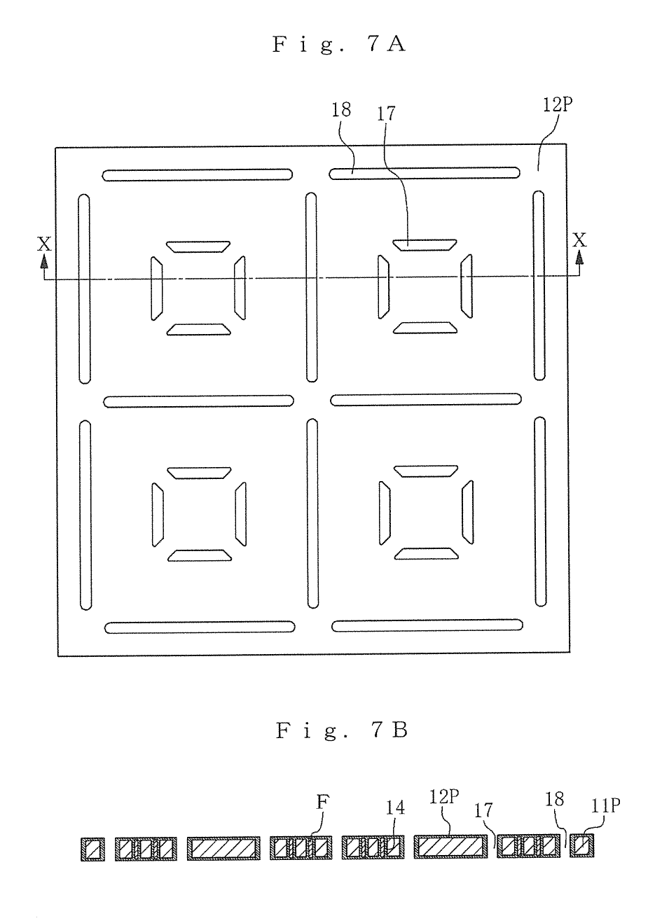

Subsequently, as shown in FIGS. 7A and 7B, the copper plated layer 12P is additionally deposited on each of the upper and lower surfaces of the resin panel 11P including an upper and a lower surfaces of the hole-filling resin F, and the whole surfaces in the first slit 17 and the second slit 18. The additionally deposited copper plated layer 12P is formed by sequentially depositing a non-electrolytic copper plated layer having a thickness of about 0.1 μm to 1 μm and an electrolytic copper plated layer having a thickness of about 5 μm to 20 μm.

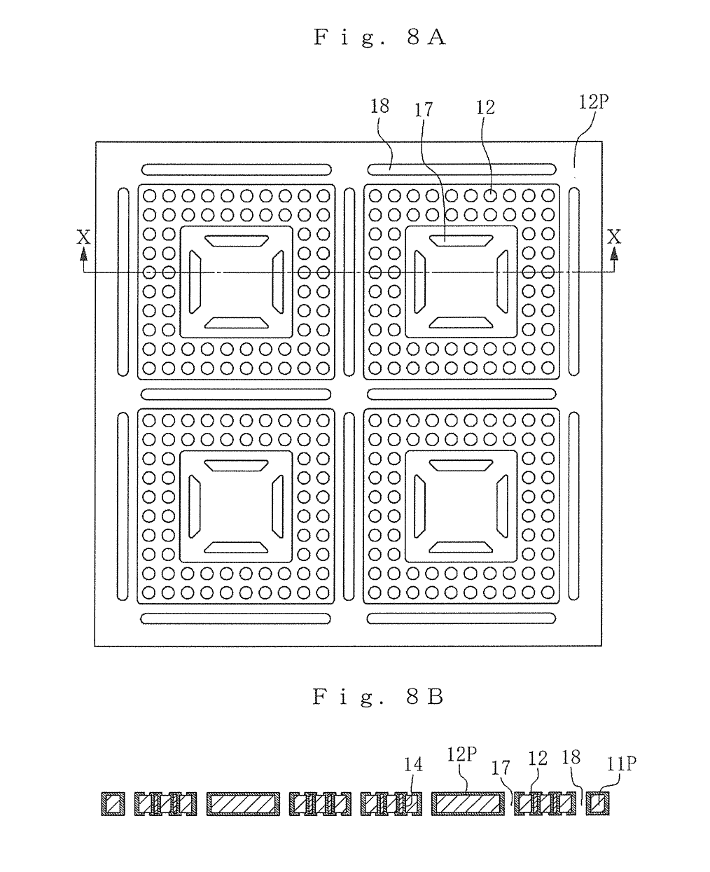

Subsequently, as shown in FIGS. 8A and 8B, the copper plated layer 12P on each of the upper and lower surfaces of the resin panel 11P is etched and patterned by a common subtractive method to form the wiring conductor 12, while the copper plate layer 12P is left as it is on the inner wall of the first slit 17 and the wall surface of the second slit 18.

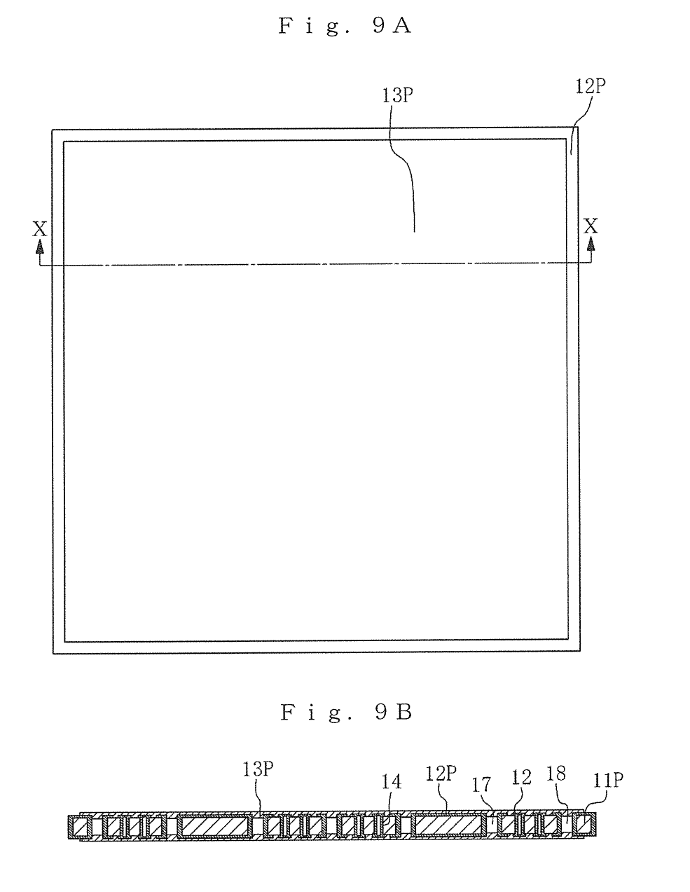

Subsequently, as shown in FIGS. 9A and 9B, a photosensitive resin film 13P for the solder resist layer 13 is attached on each of the upper and lower surfaces of the resin panel 11P having the wiring conductor 12. At this stage, the part to become the opening 10a surrounded by the first slits 17 still remains in the resin panel 11P, so that the resin film 13P can be attached without being torn or bent.

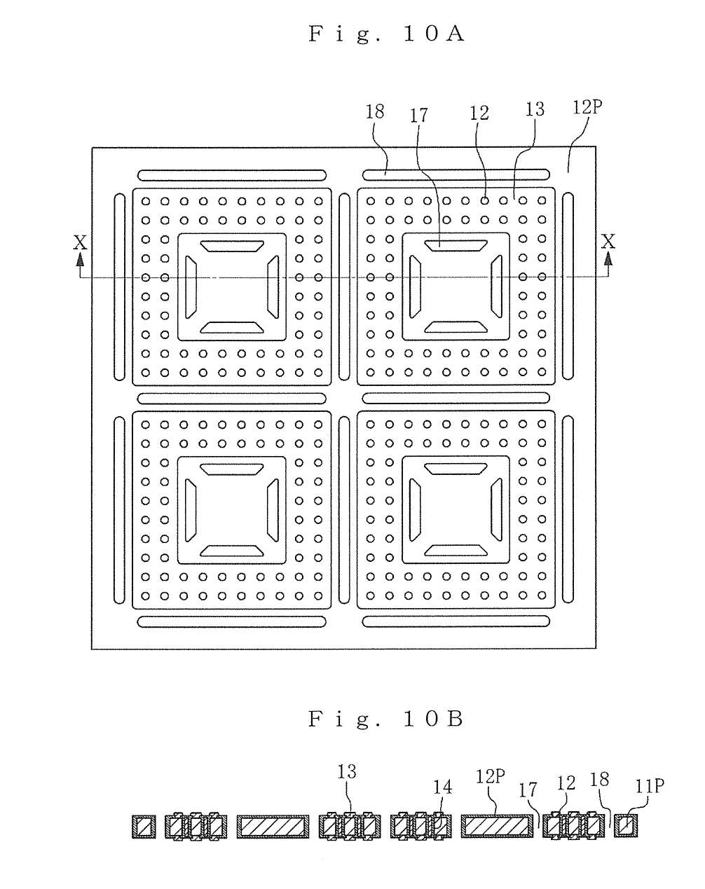

Subsequently, as shown in FIGS. 10A and 10B, the resin film 13P is patterned by a photolithography technique and thermally cured to form the solder resist layer 13.

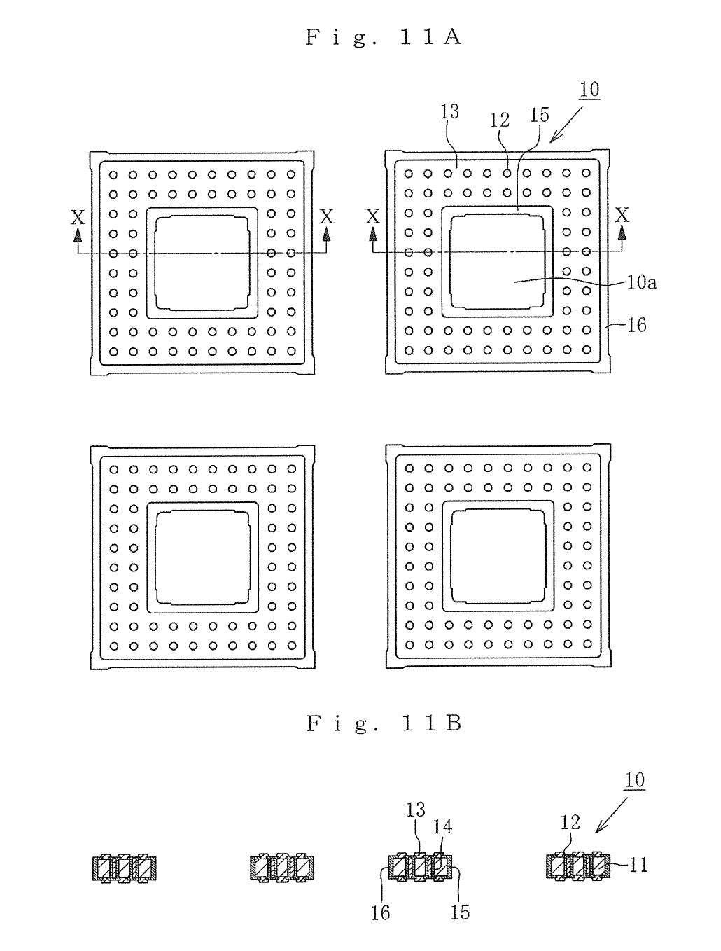

Finally, as shown in FIGS. 11A and 11B, the part to become the opening 10a is removed along the first slits 17, and an outer part of the outer periphery of the first wiring board 10 is removed along the second slits 18, whereby the first wiring board 10 is completed. Here, the copper plated layer 12P deposited on the surface in the first slit 17 is left as the inner wall conductor layer 15 on the inner wall of the opening 10a, and the copper plated layer 12P deposited on the surface in the second slit 18 is left as the outer wall conductor layer 16 on the outer peripheral wall of the insulating plate 11. Therefore, according to this method, it is possible to easily manufacture the first wiring board 10 having the inner wall conductor layer 15 on the inner wall of the opening 10a, and the outer wall conductor layer 16 on the outer peripheral wall of the insulating plate 11.

### Second Wiring Board

As shown in FIG. 1, the second wiring board 20 includes an insulating plate 21, an insulating layer 22, a wiring conductor 23, and a solder resist layer 24. The insulating plate 21 is composed of a thermosetting resin plate containing glass cloth. A plurality of through-holes 25 are formed in the insulating plate 21 from an upper surface to a lower surface. The wiring conductor 23 is deposited on each of the upper and lower surface of the insulating plate 21 and a surface in the through-hole 25. The wiring conductor 23 is formed of copper.

The insulating layer 22 is stacked on each of the upper and lower surfaces of the insulating plate 21. The insulating layer 22 is formed of a thermosetting resin. A plurality of via-holes 26 are formed in the insulating layer 22. A bottom surface of the via-hole 26 is the wiring conductor 23 deposited on the upper or lower surface of the insulating plate 21.

The wiring conductor 23 is deposited on a surface of the insulating layer 22 and a surface in the via-hole 26. The wiring conductor 23 deposited on the surface of the lower insulating layer 22 partially serves as a third connection pad 23a at a position opposed to the first connection pad 12a. The third connection pad 23a is connected to the first connection pad 12a through a first solder bump 31. Thus, the first wiring board 10 and the second wiring board 20 are bonded to each other.

The other wiring conductor 23 deposited on the surface of the lower insulating layer 22 partially serves as a fourth connection pad 23b in the opening 10a. The fourth connection pad 23b is connected to an electrode of the first electronic component E1 through a second solder bump 32.

The wiring conductor 23 deposited on the surface of the upper insulating layer 22 partially serves as a fifth connection pad 23c. The fifth connection pad 23c is connected to an electrode of the second electronic component E2 through a third solder bump 33.

Furthermore, a grounding conductor layer 27 is deposited on each of the surface of the upper insulating layer 22, the surface of the lower insulating layer 22, and an outer peripheral wall of the second wiring board 20. The conductor layer 27 is composed of a copper plated layer. The conductor layer 27 has a thickness of 5 μm to 20 μm. The conductor layer 27 is deposited on an approximately whole surface except for the third connection pad 23a, the fourth connection pad 23b, the fifth connection pad 23c, and their vicinities. The grounding conductor layer 27 is connected to each of the inner wall conductor layer 15 and the outer wall conductor layer 16 of the first wiring board 10 through a fillet-shaped solder 34. Thus, the grounding conductor layer 27 is provided from the upper surface to the lower surface of the second wiring board 20 through the outer wall, and the conductor layer 27 is connected to the inner wall conductor layer 15 and the outer wall conductor layer 16 of the first wiring board 10 through the solder 34, so that heat generated from the first electronic component E1 and the second electronic component E2 at the time of the operation can be transmitted through the inner wall conductor layer 15 and the outer wall conductor layer 16 and externally released. Therefore, it is possible to enhance an ability to externally release the heat generated from the first electronic component E1 and the second electronic component E2 mounted on the second wiring board 20 during their operations.

The second wiring board 20 includes the solder resist layer 24 which is deposited on each of the surfaces of the upper and lower insulating layers 22. The lower solder resist layer 24 has an opening to expose the third connection pad 23a, and an opening to expose the fourth connection pad 23b. The lower solder resist layer 24 also has openings to expose a connection portion between the inner wall conductor layer 15 and the grounding conductor layer 27, and a connection portion between the outer wall conductor layer 16 and the grounding conductor layer 27. The upper solder resist layer 24 has an opening to expose the fifth connection pad 23c.

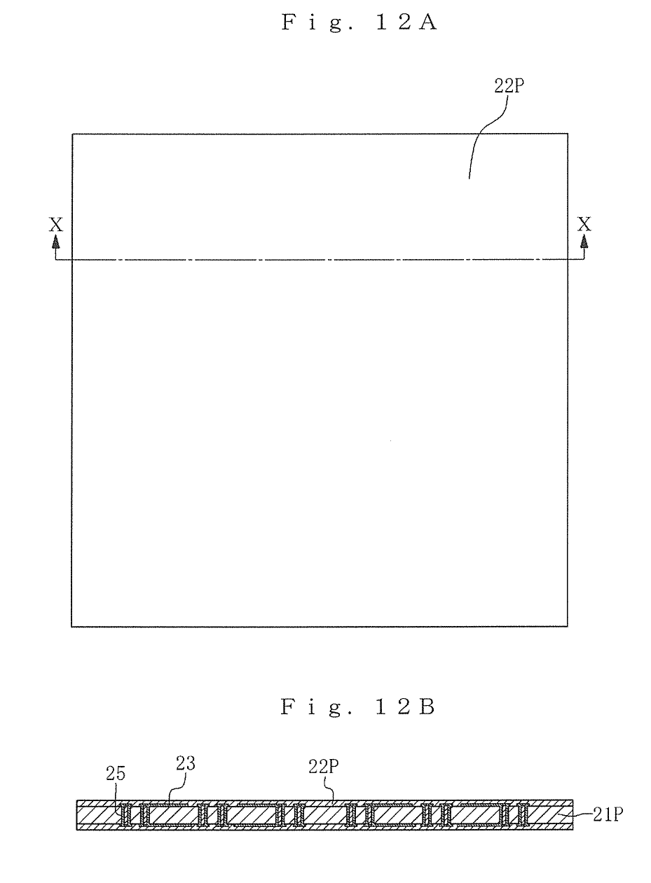

A method for manufacturing the second wiring board 20 will be described with reference to FIGS. 12A and 12B to 18A to 18B. FIGS. 12A and 12B to 18A and 18B show a case where the four second wiring boards 20 are formed from one panel. FIGS. 12A to 18A show schematic top views of the panel, and FIGS. 12B to 18B show schematic cross-sectional views taken along lines X-X in FIGS. 12A to 18A, respectively.

First, as shown in FIGS. 12A and 12B, a resin panel 21P is prepared as the insulating plate 21 having the through-holes 25 and the wiring conductor 23, and a resin film. 22P as the insulating layer 22 is stacked on each of an upper and a lower surfaces of the resin panel 21P by hot-pressing. The resin film 22P is formed of an uncured thermosetting resin. The resin panel 21P as the insulating plate 21 having the through-holes 25 and the wiring conductor 23 is manufactured through similar steps except for providing the first slit 17 and the second slit 18 in the resin panel 11P.

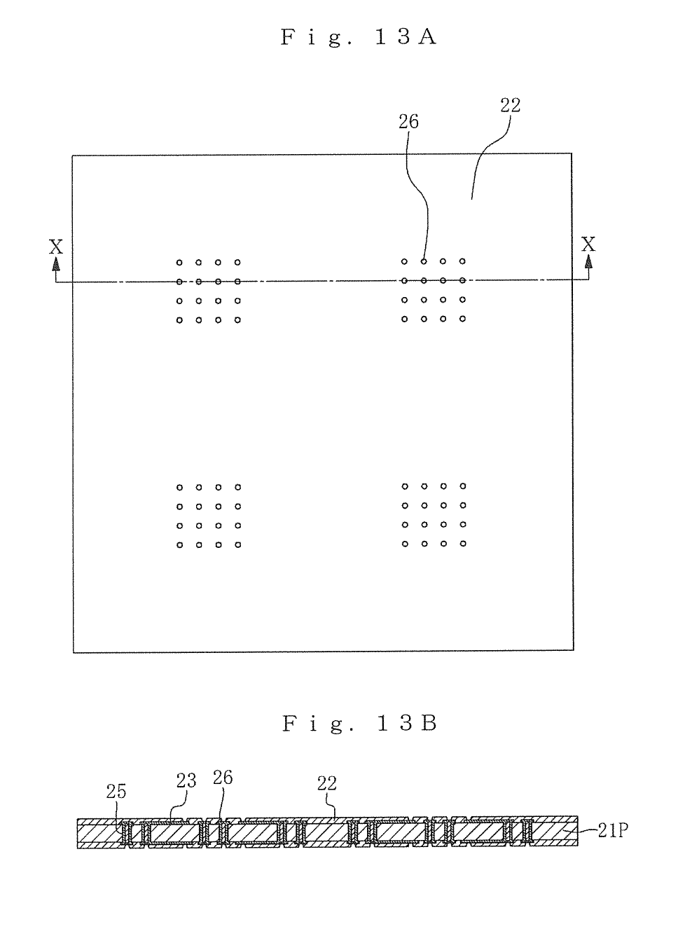

Subsequently, as shown in FIGS. 13A and 13B, the resin film 22P on each of the upper and the lower surfaces is thermally cured to form the insulating layer 22, and the via-holes 26 are formed by the laser processing.

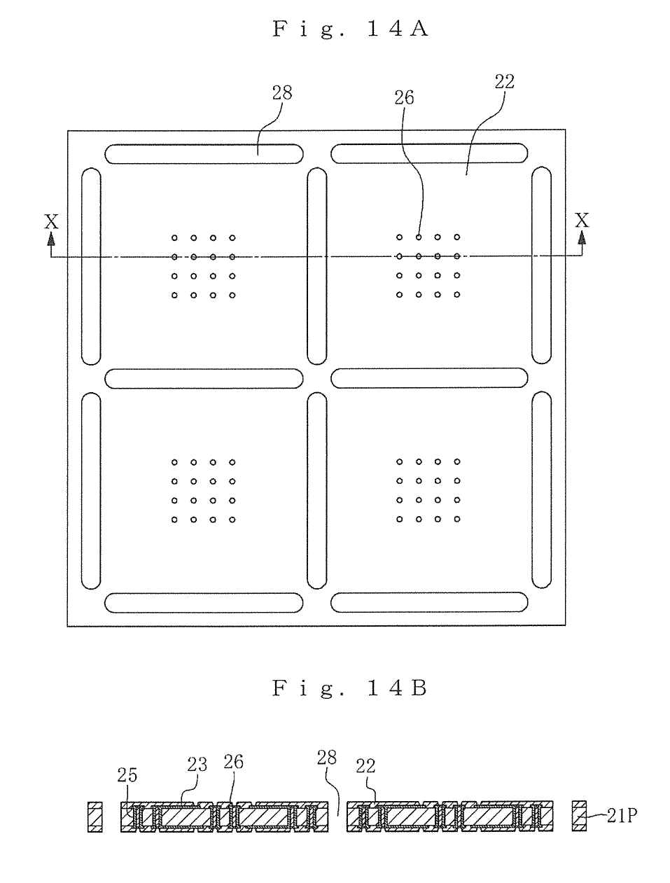

Subsequently, as shown in FIGS. 14A and 14B, a slit 28 is formed so as to penetrate the resin panel 21P and the insulating layer 22, along each side of the outer periphery of the insulating plate 21. The slit 28 is formed by router processing.

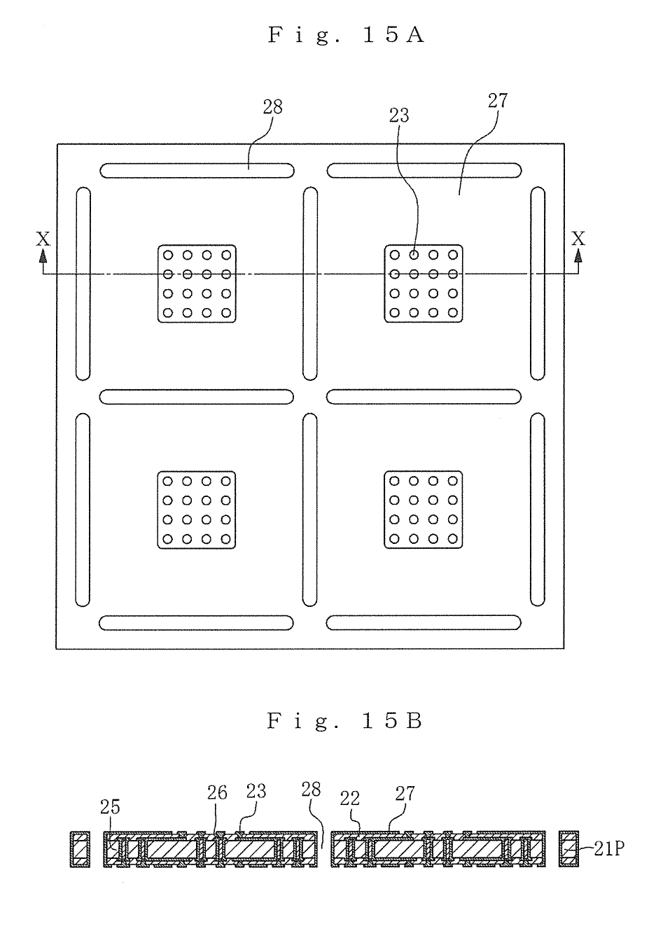

Subsequently, as shown in FIGS. 15A and 15B, the wiring conductor 23 is formed on surfaces of the upper and lower insulating layers 22, and the grounding conductor layer 27 is formed on the surfaces of the upper and lower insulating layers 22 and a surface in the slit 28. The wiring conductor 23 and the conductor layer 27 are formed by a common semi-additive method.

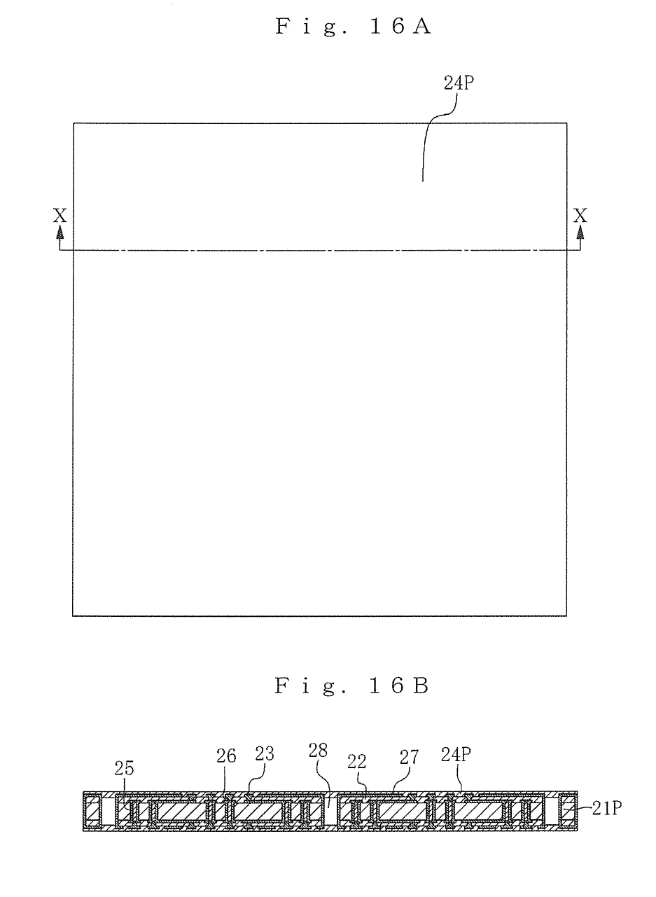

Subsequently, as shown in FIGS. 16A and 16B, a photosensitive resin film 24P as the solder resist layer 24 is attached to the surfaces of the upper and lower insulating layers 22 having the wiring conductor 23 and the grounding conductor layer 27.

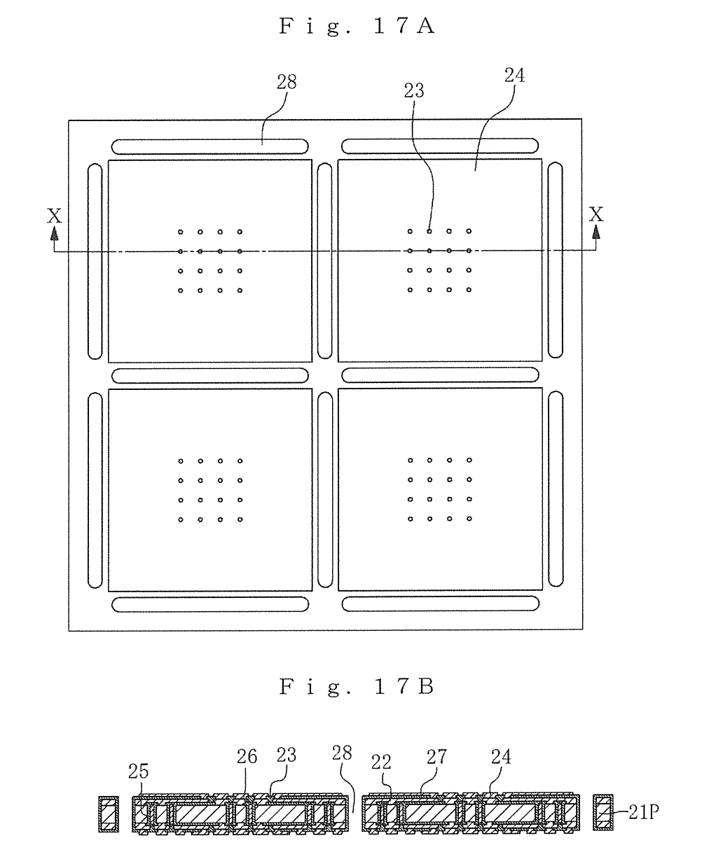

Subsequently, as shown in FIGS. 17A and 17B, the resin film. 24P is patterned by the photolithography technique and thermally cured, whereby the solder resist layer 24 is formed.

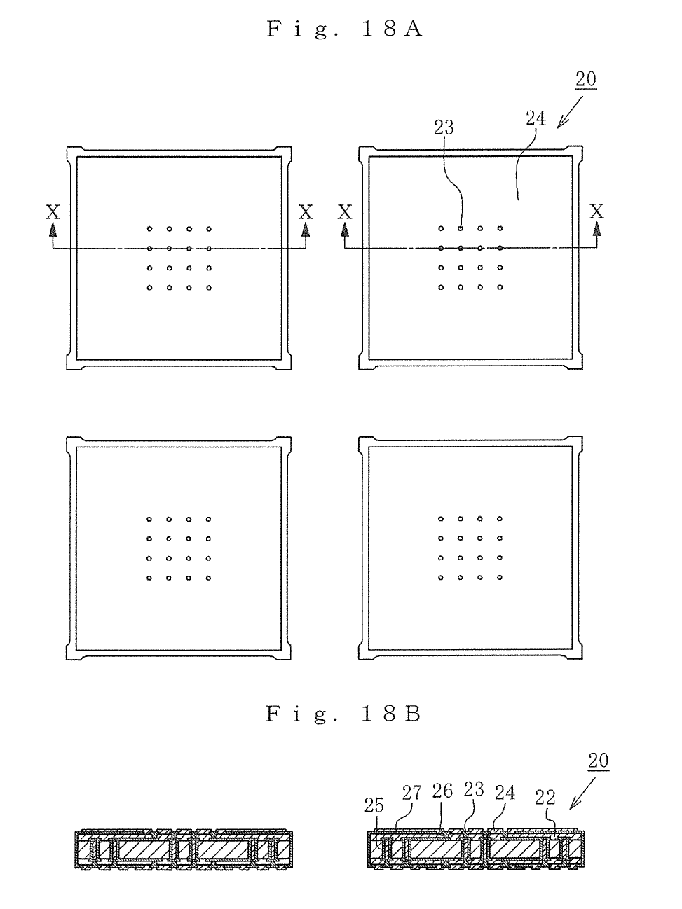

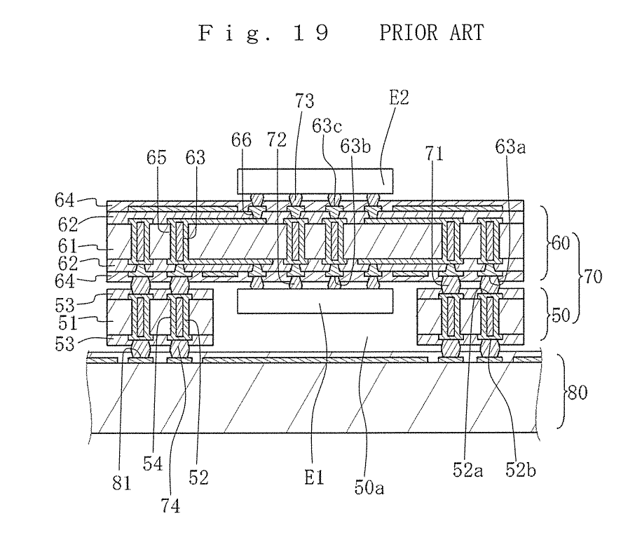

Finally, as shown in FIGS. 18A and 18B, an outside of the outer periphery of the second wiring board 20 is removed by cutting along the slits 28, whereby the second wiring board 20 is completed. Thus, the copper plated layer deposited in the slit 28 is left as the grounding conductor layer 27 on the outer peripheral wall of the insulating plate 21. Therefore, according to this method, it is possible to easily manufacture the second wiring board 20 having the grounding conductor layer 27 on the outer peripheral wall.

As shown in FIG. 1, the composite wiring board 30 can be mounted on the third wiring board 40. After the first electronic component E1 and the second electronic component E2 have been mounted on the upper and lower surfaces of the second wiring board 20, the second connection pad 12b is connected to a connection pad 41 of the third wiring board 40 such as the mother board through a solder bump 35, and the inner wall conductor layer 15 and the outer wall conductor layer 16 of the first wiring board 10 are connected to a grounding conductor layer 42 of the third wiring board 40 through a fillet-shaped solder 36. In this way, the composite wiring board 30 is mounted on the third wiring board 40. Since the inner wall conductor layer 15 and the outer wall conductor layer 16 of the first wiring board 10 are connected to the grounding conductor layer 42 of the third wiring board 40 through the solder 36, there can be provided the mounting structure which is high in electromagnetic shielding effect for the electronic component E1 housed internally, and high in ability to externally release the heat generated at the time of the operations of the mounted electronic components E1 and E2.

The present invention is not limited to the above-described embodiment, and can be variously modified or improved within the scope of the claim. For example, according to the above embodiment, the inner wall conductor layer 15 and the outer wall conductor layer 16 are both provided in the first wiring board 10, but only the inner wall conductor layer 15 may be provided. Furthermore, according to the above embodiment, the grounding conductor layer 27 is provided on the upper and lower surfaces and the outer peripheral wall of the second wiring board 20, but the grounding conductor layer 27 may be only provided on the lower surface of the second wiring board 20.

What is claimed is:

1. A composite wiring board comprising:
a first wiring board having an opening for housing an electronic component, and including a plurality of first connection pads on a first surface and a plurality of second connection pads on a second surface; and
a second wiring board having the electronic component mounted on a first surface, including a third connection pad provided outside the mounted electronic component on the first surface and bonded to the first connection pad through a solder, and disposed on the first surface of the first wiring board so as to cover the opening with the first surface, wherein
a grounding inner wall conductor layer is deposited on an inner wall of the opening from the first surface to the second surface around the electronic component, and a grounding conductor layer is deposited on the first surface of the second wiring board and connected to the inner wall conductor layer through a solder.

2. The composite wiring board according to claim 1, wherein
the first wiring board includes a through-hole, and the first connection pad and the second connection pad are connected to each other through a wiring conductor in the through-hole.

3. The composite wiring board according to claim 1, wherein
an outer wall conductor layer is deposited on an outer peripheral wall of the first wiring board from the first surface to the second surface.

4. The composite wiring board according to claim 1, wherein
a fourth connection pad is further formed on the first surface of the second wiring board and connected to the electronic component.

5. The composite wiring board according to claim 1, wherein
a fifth connection pad is further formed on the second surface of the second wiring board and connected to another electronic component.

6. The composite wiring board according to claim 1, wherein
a grounding conductor layer is provided at least on the first surface of the second wiring board.

7. The composite wiring board according to claim 6, wherein
the grounding conductor layer is connected to the inner wall conductor layer and an outer wall conductor layer of the first wiring board through a solder.

8. A mounting structure, wherein
the composite wiring board having the electronic component according to claim 1 is mounted on a third wiring board including a connection pad bonded to the second connection pad through a solder, and a grounding conductor layer bonded to the inner wall conductor layer through a solder.
